(19) United States
(12) Patent Application Publication
(10) Pub. No.: US 2024/0074184 A1
(43) Pub. Date: Feb. 29, 2024

(54) ELECTRONIC DEVICES COMPRISING A STEPPED PILLAR REGION, AND RELATED METHODS

(71) Applicant: Micron Technology, Inc., Boise, ID (US)

(72) Inventors: Masaaki Higuchi, Tokyo (JP); Yoshiaki Fukuzumi, Tokyo (JP); Hirokazu Ishigaki, Tokyo (JP)

(21) Appl. No.: 17/897,976

(22) Filed: Aug. 29, 2022

(51) Int. Cl. H01L 27/11582; G11C 16/04; H01L 27/11519; H01L 27/11524; H01L 27/11556; H01L 27/11565; H01L 27/1157

(52) U.S. Cl. CPC H01L 27/11582; G11C 16/0483; H01L 27/11519; H01L 27/11524; H01L 27/11556; H01L 27/11565; H01L 27/1157

(57) ABSTRACT

An electronic device comprises memory pillars comprising a channel material. The memory pillars extend through both a cell region and a lateral contact region. A portion of the memory pillars in the lateral contact region comprise at least one first step and at least one second step. The electronic device comprises a source contact in direct contact with the channel material in the at least one second step of the portion of the memory pillars in the lateral contact region. Additional electronic devices and methods of forming an electronic device are also disclosed.

### TECHNICAL FIELD

Embodiments of the disclosure relate to the field of electronic device design and fabrication. More particularly, the disclosure relates to electronic devices having channel materials of different thicknesses in pillars and to methods for forming the electronic devices.

### BACKGROUND

Memory devices provide data storage for electronic systems. A Flash memory device is one of various memory device types and has numerous uses in modern computers and other electrical devices. A conventional Flash memory device may include a memory array that has a large number of charge storage devices (e.g., memory cells, such as non-volatile memory cells) arranged in rows and columns. In a NAND architecture type of Flash memory, memory cells arranged in a column are coupled in series, and a first memory cell of the column is coupled to a data line (e.g., a bit line). In a three-dimensional (3D) NAND memory device, not only are the memory cells arranged in rows and columns in a horizontal array, but tiers of the horizontal arrays are stacked over one another (e.g., as vertical strings of memory cells) to provide a 3D array of the memory cells. The stack of tiers vertically alternate conductive materials with dielectric materials, with the conductive materials functioning as access lines (e.g., word lines) and gate structures (e.g., control gates) for the memory cells. Pillars comprising channels and tunneling structures extend along and form portions of the memory cells of individual vertical strings of memory cells. A drain end of a string is adjacent one of the top or bottom of the pillar, while a source end of the string is adjacent the other of the top or bottom of the pillar. The drain end is operably connected to a bit line, and the source end is operably connected to a source line. A 3D NAND memory device also includes electrical connections between, e.g., access lines (e.g., word lines) and other conductive structures of the device so that the memory cells of the vertical strings can be selected for writing, reading, and erasing operations.

In conventional 3D NAND electronic devices, the pillars including the channels are formed using multiple polysilicon materials, and lateral contact with the channels is achieved by removing a sacrificial material and replacing it with a laterally-oriented, doped polysilicon material. However, removing the sacrificial material may result in damage to the cell films of the pillars by forming pin holes in the channels through which etchants may pass. In addition, after replacing the sacrificial material with the doped polysilicon material, dopants may pass through the pin holes and reach the cell region of the pillar resulting in low initial threshold voltage. As cell transistors have large leakage current when the doped polysilicon material reaches the cell region, the cell cannot program the memory due to not changing threshold voltage. Therefore, designing and fabricating electronic devices with desired electrical performance continues to be challenging.

### BRIEF DESCRIPTION OF THE DRAWINGS

FIG. 1A is a cross-sectional, schematic illustration of an electronic device, in accordance with embodiments of the disclosure;

FIGS. 1B and 1C are top-down views of an electronic device, in accordance with embodiments of the disclosure;

FIG. 1D is an orthographic view of an electronic device, in accordance with embodiments of the disclosure;

FIGS. 2A through 10C are cross-sectional, schematic illustrations during various processing acts to fabricate an electronic device, in accordance with embodiments of the disclosure;

FIGS. 10D and 10E are top-down views of an electronic device, in accordance with embodiments of the disclosure;

FIGS. 11A through 11E are simplified cross-sectional views showing a method of forming an electronic device, in accordance with other embodiments of the disclosure;

FIGS. 11F and 11G are top-down views of an electronic device, in accordance with embodiments of the disclosure;

FIGS. 12A through 12E are simplified cross-sectional views showing a method of forming an electronic device, in accordance with yet other embodiments of the disclosure;

FIGS. 12F and 12G are top-down views of an electronic device, in accordance with embodiments of the disclosure;

FIG. 13 is a partial, cutaway, perspective, schematic illustration of an apparatus including one or more electronic devices, in accordance with embodiments of the disclosure;

FIG. 14 is a block diagram of an electronic system including one or more electronic devices, in accordance with embodiments of the disclosure;

FIG. 15 is a block diagram of a processor-based system including one or more electronic devices, in accordance with embodiments of the disclosure; and

FIG. 16 is a block diagram of an additional processor-based system including one or more electronic devices, in accordance with embodiments of the disclosure.

### DETAILED DESCRIPTION

The illustrations included herewith are not meant to be actual views of any particular systems, electronic device structures, electronic devices, or integrated circuits thereof, but are merely idealized representations that are employed to describe embodiments herein. Elements and features common between figures may retain the same numerical designation except that, for ease of following the description, reference numerals begin with the number of the drawing on which the elements are introduced or most fully described.

The following description provides specific details, such as material types, material thicknesses, and process conditions in order to provide a thorough description of embodiments described herein. However, a person of ordinary skill in the art will understand that the embodiments disclosed herein may be practiced without employing these specific details. Indeed, the embodiments may be practiced in conjunction with conventional fabrication techniques employed in the semiconductor industry. In addition, the description provided herein does not form a complete description of an electronic device or a complete process flow for manufacturing the electronic device and the structures described below do not form a complete electronic device. Only those process acts and structures necessary to understand the embodiments described herein are described in detail below. Additional acts to form a complete electronic device may be performed by conventional techniques.

The fabrication processes described herein do not form a complete process flow for processing electronic devices (e.g., devices, apparatus, systems) or the structures thereof. The remainder of the process flow is known to those of ordinary skill in the art. Accordingly, only the methods and structures necessary to understand embodiments of the electronic devices and methods are described herein.

Unless the context indicates otherwise, the materials described herein may be formed by any suitable technique including, but not limited to, spin coating, blanket coating, chemical vapor deposition (“CVD”), atomic layer deposition (“ALD”), plasma enhanced ALD, physical vapor deposition (“PVD”) (e.g., sputtering), or epitaxial growth. Alternatively, the materials may be grown in situ. Depending on the specific material to be formed, the technique for depositing or growing the material may be selected by a person of ordinary skill in the art unless the context indicates otherwise. The removal of materials may be accomplished by any suitable technique including, but not limited to, etching (e.g., dry etching, wet etching, vapor etching), ion milling, abrasive planarization (e.g., chemical-mechanical planarization), or other known methods unless the context indicates otherwise.

Drawings presented herein are for illustrative purposes only, and are not meant to be actual views of any particular material, component, structure, electronic device, or system. Variations from the shapes depicted in the drawings as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims. The drawings are not necessarily to scale. Additionally, elements common between figures may retain the same numerical designation.

As used herein, the singular forms “a,” “an,” and “the” are intended to include the plural forms as well, unless the context clearly indicates otherwise.

As used herein, “and/or” includes any and all combinations of one or more of the associated listed items.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the terms “comprising,” “including,” “containing,” “characterized by,” and grammatical equivalents thereof are inclusive or open-ended terms that do not exclude additional, unrecited elements or method steps, but also include the more restrictive terms “consisting of” and “consisting essentially of” and grammatical equivalents thereof.

As used herein, the term “conductive material” means and includes an electrically conductive material. The conductive material may include, but is not limited to, one or more of a doped polysilicon, undoped polysilicon, a metal, an alloy, a conductive metal oxide, a conductive metal nitride, a conductive metal silicide, and a conductively doped semiconductor material. By way of example only, the conductive material may be one or more of tungsten (W), tungsten nitride (WN_{y}), nickel (Ni), tantalum (Ta), tantalum nitride (TaN_{y}), tantalum silicide (TaSiₓ), platinum (Pt), copper (Cu), silver (Ag), gold (Au), aluminum (Al), molybdenum (Mo), titanium (Ti), titanium nitride (TiN_{y}), titanium silicide (TiSiₓ), titanium silicon nitride (TiSiₓN_{y}), titanium aluminum nitride (TiAlₓN_{y}), molybdenum nitride (MoNₓ), iridium (Ir), iridium oxide (IrO_{z}), ruthenium (Ru), ruthenium oxide (RuO_{z}), n-doped polysilicon, p-doped polysilicon, undoped polysilicon, and conductively doped silicon, where x, y, or z are integers or non-integers.

As used herein, the term “configured” refers to a size, shape, material composition, and arrangement of one or more of at least one structure and at least one apparatus facilitating operation of one or more of the structure and the apparatus in a pre-determined way.

As used herein, the phrase “coupled to” refers to structures operably connected with each other, such as electrically connected through a direct ohmic connection or through an indirect connection (e.g., via another structure).

As used herein, the term “dielectric material” means and includes an electrically insulative material. The dielectric material may include, but is not limited to, one or more of an insulative oxide material, an insulative nitride material, an insulative oxynitride material, an insulative carboxynitride material, and/or air. A dielectric oxide material may be an oxide material, a metal oxide material, or a combination thereof. The dielectric oxide material may include, but is not limited to, a silicon oxide (SiOₓ, silicon dioxide (SiO₂)), phosphosilicate glass (PSG), borosilicate glass (BSG), borophosphosilicate glass (BPSG), fluorosilicate glass (FSG), aluminum oxide (AlOₓ), barium oxide, gadolinium oxide (GdOₓ), hafnium oxide (HfOₓ), magnesium oxide (MgOₓ), molybdenum oxide, niobium oxide (NbOₓ), strontium oxide, tantalum oxide (TaOₓ), titanium oxide (TiOₓ), yttrium oxide, zirconium oxide (ZrOₓ), hafnium silicate, a dielectric oxynitride material (e.g., SiOₓN_{y}), a dielectric carbon nitride material (SiCN), a dielectric carboxynitride material (e.g., SiOₓC_{z}N_{y}), a combination thereof, or a combination of one or more of the listed materials with silicon oxide, where values of “x,” “y,” and “z” may be integers or may be non-integers. A dielectric nitride material may include, but is not limited to, silicon nitride. A dielectric oxynitride material may include, but is not limited to, a silicon oxynitride (SiOₓN_{y}). A dielectric carboxynitride material may include, but is not limited to, a silicon carboxynitride (SiOₓC_{z}N_{y}). The dielectric material may be a stoichiometric compound or a non-stoichiometric compound.

As used herein, the term “electronic device” includes, without limitation, a memory device, as well as semiconductor devices which may or may not incorporate memory, such as a logic device, a processor device, or a radiofrequency (RF) device. Further, an electronic device may incorporate memory in addition to other functions such as, for example, a so-called “system on a chip” (SoC) including a processor and memory, or an electronic device including logic and memory. The electronic device may, for example, be a 3D electronic device, such as a 3D NAND Flash memory device.

As used herein, reference to an element as being “on” or “over” another element means and includes the element being directly on top of, adjacent to (e.g., laterally adjacent to, vertically adjacent to), underneath, or in direct contact with the other element. It also includes the element being indirectly on top of, adjacent to (e.g., laterally adjacent to, vertically adjacent to), underneath, or near the other element, with other elements present therebetween. In contrast, when an element is referred to as being “directly on” or “directly adjacent to” another element, no intervening elements are present.

As used herein, the terms “opening” and “slit” mean and include a volume extending through at least one structure or at least one material, leaving a void (e.g., gap) in that at least one structure or at least one material, or a volume extending between structures or materials, leaving a gap between the structures or materials. Unless otherwise described, an “opening” and/or “slit” is not necessarily empty of material. That is, an “opening” and/or “slit” is not necessarily void space. An “opening” and/or “slit” formed in or between structures or materials may comprise structure(s) or material(s) other than that in or between which the opening is formed. And, structure(s) or material(s) “exposed” within an “opening” and/or “slit” is (are) not necessarily in contact with an atmosphere or non-solid environment. Structure(s) or material(s) “exposed” within an “opening” and/or “slit” may be adjacent or in contact with other structure(s) or material(s) that is (are) disposed within the “opening” and/or “slit.”

As used herein, the term “sacrificial,” when used in reference to a material or a structure, means and includes a material or structure that is formed during a fabrication process but at least a portion of which is removed (e.g., substantially removed) prior to completion of the fabrication process. The sacrificial material or sacrificial structure may be present in some portions of the electronic device and absent in other portions of the electronic device.

As used herein, the terms “selectively removable” or “selectively etchable” mean and include a material that exhibits a greater etch rate responsive to exposure to a given etch chemistry and/or process conditions (collectively referred to as etch conditions) relative to another material exposed to the same etch chemistry and/or process conditions. For example, the material may exhibit an etch rate that is at least about five times greater than the etch rate of another material, such as an etch rate of about ten times greater, about twenty times greater, or about forty times greater than the etch rate of the another material. Etch chemistries and etch conditions for selectively etching a desired material may be selected by a person of ordinary skill in the art.

As used herein, the term “substantially” in reference to a given parameter, property, or condition means and includes to a degree that one of ordinary skill in the art would understand that the given parameter, property, or condition is met with a degree of variance, such as within acceptable manufacturing tolerances. By way of example, depending on the particular parameter, property, or condition that is substantially met, the parameter, property, or condition may be at least 90.0% met, at least 95.0% met, at least 99.0% met, or even at least 99.9% met.

As used herein, the term “substrate” means and includes a material (e.g., a base material) or construction upon which additional materials or components, such as those within memory cells, are formed. The substrate may be an electronic substrate, a semiconductor substrate, a base semiconductor layer on a supporting structure, an electrode, an electronic substrate having one or more materials, layers, structures, or regions formed thereon, or a semiconductor substrate having one or more materials, layers, structures, or regions formed thereon. The materials on the electronic substrate or semiconductor substrate may include, but are not limited to, semiconductive materials, insulating materials, conductive materials, etc. The substrate may be a conventional silicon substrate or other bulk substrate comprising a layer of semiconductive material. As used herein, the term “bulk substrate” means and includes not only silicon wafers, but also silicon-on-insulator (“SOI”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped. Furthermore, when reference is made to a “substrate” or “base material” in the following description, previous process acts may have been conducted to form materials or structures in or on the substrate or base material.

As used herein, the terms “vertical,” “longitudinal,” “horizontal,” and “lateral” are in reference to a major plane of a structure and are not necessarily defined by Earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure.

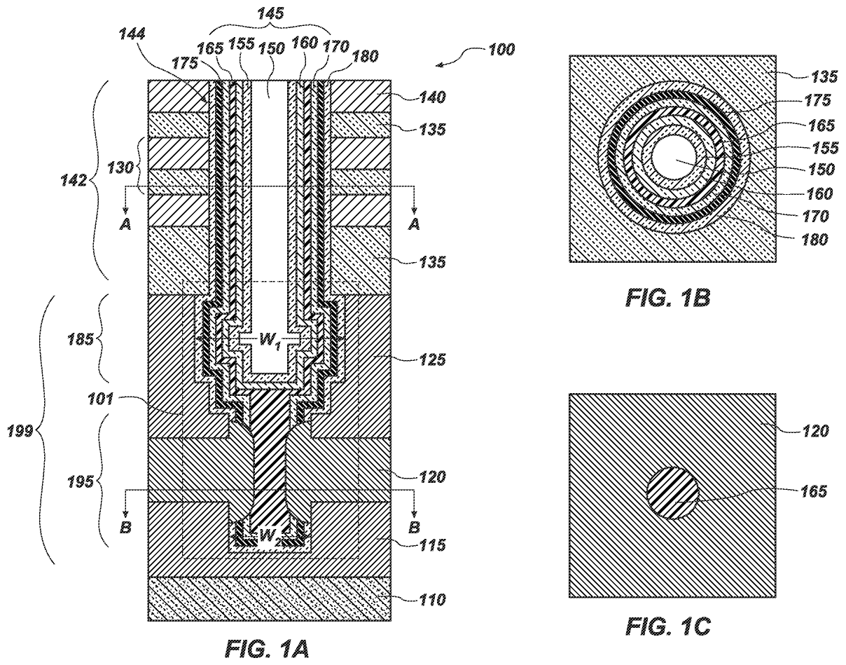

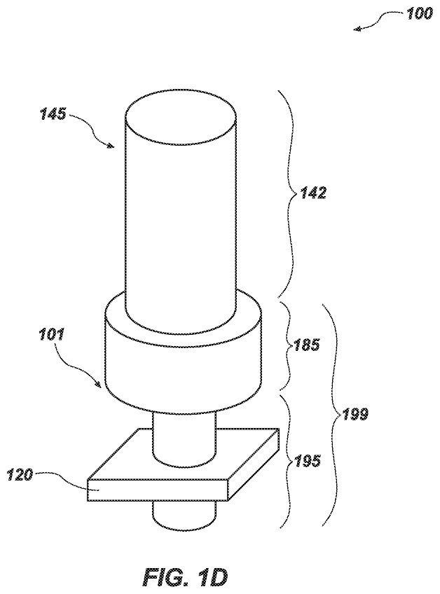

An electronic device 100 according to some embodiments of the disclosure is shown in FIG. 1A. The electronic device 100 includes a conductive material 110 (e.g., a conductive liner material), a bottom semiconductive material 115, a source contact 120, and a top semiconductive material 125. The conductive material 110 is adjacent to (e.g., directly over) a base material (not shown), and the bottom semiconductive material 115 is adjacent to (e.g., vertically adjacent to, directly over) the conductive material 110. The source contact 120 is adjacent to (e.g., vertically adjacent to, directly over) the bottom semiconductive material 115. The top semiconductive material 125 is adjacent to (e.g., vertically adjacent to, directly over) the source contact 120. The bottom semiconductive material 115, the source contact 120, and the top semiconductive material 125 form a lateral contact region 199.

Tiers 130 of alternating insulative materials 135 and conductive materials 140 are adjacent to (e.g., vertically adjacent to, directly over) the top semiconductive material 125. The tiers 130 form a cell region 142 adjacent to the top semiconductive material 125, which includes memory cells 144 located at intersections of the conductive materials 140 and cell films of pillars 145. The memory cells 144 are laterally adjacent to the conductive materials 140 of the tiers 130. Some of the conductive materials 140 are configured as so-called “replacement gate” word lines (e.g., word lines formed by a so-called “replacement gate” or “gate late” process). One or more of the tiers 130 proximal to the top semiconductive material 125 functions as a select gate source (SGS) and one or more of the tiers 130 distal to the top semiconductive material 125 functions as a select gate drain (SGD).

The pillars 145 (e.g., memory pillars) extend through the tiers 130, the top semiconductive material 125, the source contact 120, and at least partially into the bottom semiconductive material 115. The pillars 145 include a fill material 150, an oxide material 155, an oxidation material 160, a channel material 165 (e.g., hollow channel, doped hollow channel), a tunnel dielectric material 170, a charge trap material 175, and a charge blocking material 180. The tunnel dielectric material 170, the charge trap material 175, and the charge blocking material 180 function as tunneling structures of the pillars 145 of the electronic device 100. A portion of the pillars 145 includes a stepped pillar region 101 that extends through the top semiconductive material 125 and the source contact 120, and into the bottom semiconductive material 115. A portion of the stepped pillar region 101 is above the source contact 120 and an additional portion of the pillars 145 is below the source contact 120, with the channel material 165 extending through the source contact 120. The stepped pillar region 101 may include a first step 185 and a second step 195. The pillars 145 include a fill material 150, an oxide material 155, an oxidation material 160, a channel material 165 (e.g., a hollow channel, a doped hollow channel), a tunnel dielectric material 170, a charge trap material 175, and a charge blocking material 180. The tunnel dielectric material 170, the charge trap material 175, and the charge blocking material 180 function as tunneling structures of the pillars 145 of the electronic device 100.

The channel material 165 has a different thickness in the cell region 142 than in the lateral contact region 199. For example, the channel material 165 in the cell region 142 may be relatively thinner than the channel material 165 in the lateral contact region 199. The thickness of the channel material 165 may also differ between the first step 185 and the second step 195, with the thickness in the first step 185 being relatively thinner than the thickness in the second step 195. A chemical composition of the channel material 165 may also vary between the cell region 142 and the lateral contact region 199. For instance, the channel material 165 proximal to the source contact 120 may include a relatively greater dopant concentration than a dopant concentration of the channel material 165 proximal to the lateral contact region 199.

FIG. 1B shows a top-down view of the electronic device 100 along line A-A of FIG. 1A. Line A-A is a cross-sectional cut through the insulative material 135 and the pillars 145 in the memory cell region 142. The pillars 145 in the memory cell region 142 include the fill material 150, the oxide material 155, the oxidation material 160, the channel material 165, the tunnel dielectric material 170, the charge trap material 175, and the charge blocking material 180.

FIG. 1C shows a top-down view of the electronic device 100 along line B-B of FIG. 1A. Line B-B is a cross-sectional cut through the source contact 120 and the channel material 165 in the lateral contact region 199. With combined reference to FIGS. 1B and 1C, the thickness of the channel material 165 in the memory cell region 142 (FIG. 1B) is relatively thinner than the thickness of the channel material 165 in the lateral contact region 199 (FIG. 1C).

FIG. 1D is an orthographic view of the electronic device 100 in accordance with embodiments of the disclosure. The pillars 145 of the cell region 142 exhibits a relatively smaller critical dimension (CD) (e.g., diameter) than the CD of the first step 185 of the stepped pillar region 101 in the lateral contact region 199. The second step 195 of the stepped pillar region 101 in the lateral contact region 199 exhibits a relatively smaller CD (e.g., diameter) than the CD of the first step 185 of the stepped pillar region 101 and a smaller CD than the CD of the pillar 145 of the cell region 142. A width W₁ corresponds to the CD of the first step 185, and a width W2 corresponds to the CD of the second step 195 of the stepped pillar region 101 in electronic device 100.

The electronic device 100 including the different thicknesses of the channel material 165 has improved electrical performance properties while also protecting the cell films during fabrication of the electronic device 100. In addition, since the increased dopant concentration in the channel material 165 proximal to the source contact 120 is close to the SGS, the electronic device 100 has a large string current, a small erase voltage signal, and a small threshold voltage.

Since the first step 185 exhibits a relatively greater CD than the CD of the second step 195 and the CD of the pillars 145 proximal to the tiers 130 is relatively less than the CD of the first step 185, contact resistance between the channel material 165 and the source contact 120 may be decreased relative to conventional electronic devices. The decreased contact resistance results in a large string current.

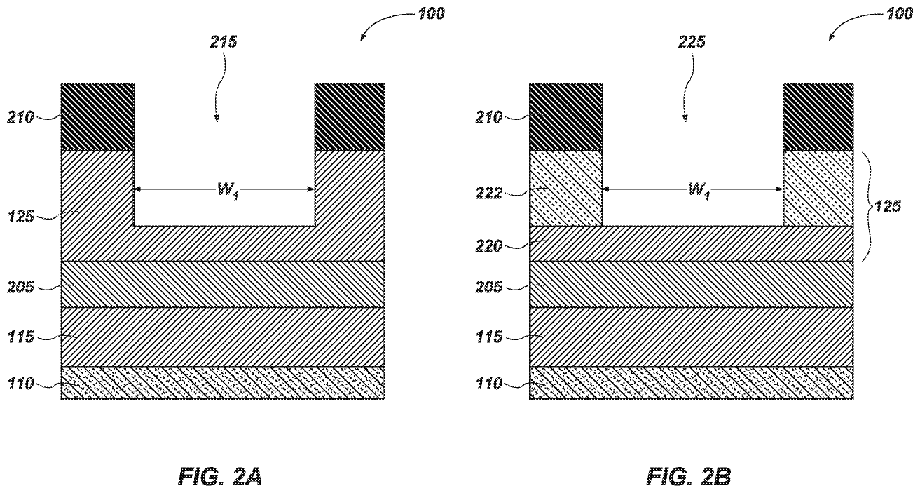

The electronic device 100 according to embodiments of the disclosure may be formed as shown in FIGS. 2A-10C. FIG. 2A shows the conductive material 110 is formed adjacent to the base material (not shown), the bottom semiconductive material 115 is formed adjacent to the conductive material 110, a source contact sacrificial material 205 is formed adjacent to the bottom semiconductive material 115, and the top semiconductive material 125 is formed adjacent to the source contact sacrificial material 205. Each of the conductive material 110, the bottom semiconductive material 115, the source contact sacrificial material 205, and the top semiconductive material 125 may be formed by conventional techniques. The conductive material 110 may be formed of and include a nitride material, such as titanium nitride, or tungsten silicide. The bottom semiconductive material 115 may be formed of and include a doped material, such as a doped polysilicon material. The doped polysilicon material may include arsenic, phosphorus, or arsenic and phosphorus as the dopant. However, the conductive material 110 and the bottom semiconductive material 115 may be formed of and include other conductive materials.

The source contact sacrificial material 205 may be formed of and include one or more materials, such as including a single material or two or more materials. The source contact sacrificial material 205 may be selectively etchable relative to other materials of the electronic device 100, such as to the bottom semiconductive material 115 and the top semiconductive material 125 or to one or more materials of the pillars 145. By way of example only, the source contact sacrificial material 205 may include a dielectric material, such as a silicon oxide material, a silicon nitride material, or a doped polysilicon material. Removal of the source contact sacrificial material 205 provides lateral access for the subsequently formed source contact 120 to contact the pillars 145. A location of the source contact sacrificial material 205 corresponds to the location at which the source contact 120 is ultimately formed, and a total thickness of the as-formed source contact sacrificial material 205 may be determined by a desired thickness of the source contact 120 (see FIGS. 1A and 1D).

The top semiconductive material 125 may be formed of and include a doped material, such as a doped polysilicon material. Alternatively, the top semiconductive material 125 may be formed of and include silicon-germanium (SiGe). However, the top semiconductive material 125 may be formed of and include other conductive materials.

A mask material is formed adjacent to the top semiconductive material 125 and may be formed of and include one or more of a photoresist material, a dielectric antireflective coating (DARC) material, a magnesium oxide (MgOx), and a doped carbon (such as tungsten-doped carbon, tantalum-doped carbon, boron-doped carbon, or silicon doped carbon). Alternatively, the mask material may be formed of and include silicon oxide, silicon nitride, a carbon doped silicon oxide, or a carbon doped silicon nitride. The mask material may be patterned by conventional techniques to form a patterned mask material 210 that exposes a portion of the top semiconductive material 125. The patterned mask material 210 is utilized to form an opening 215 by removing a portion of the top semiconductive material 125. The portions of the top semiconductive material 125 may be removed by one or more conventional etch processes, such as a conventional dry etch process. A width W₁ of the opening 215 may correspond to a width of the first step 185 of the stepped pillar region 101 in electronic device 100 (FIG. 1A). The width W₁ of the opening 215 may range from about 50 nm to about 150 nm, such as from about 75 nm to about 125 nm, from about 85 nm to about 115 nm, from about 95 nm to about 105 nm, or from about 75 nm to about 100 nm.

While FIG. 2A shows the top semiconductive material 125 as a single material, the top semiconductive material 125 may include a first material 220 and a second material 222, as shown in FIG. 2B. The first material 220 may be formed of and include a doped material, such as a doped polysilicon material. The first material 220 is formed adjacent to the source contact sacrificial material 205, and the second material 222 is formed adjacent to (e.g., over) the second material 222. The second material 222 may be formed of and include a dielectric material. Similar to the process described with reference to FIG. 2A, a mask material is formed adjacent to the second material 222 and may be formed of and include one or more of a photoresist material, a dielectric antireflective coating (DARC) material, a magnesium oxide (MgOx), and a doped carbon (such as tungsten-doped carbon, tantalum-doped carbon, boron-doped carbon, or silicon doped carbon). The mask material may be patterned by conventional techniques to form the patterned mask material 210 and to expose a portion of the second material 222 and the top semiconductive material 125. The patterned mask material 210 is utilized to form an opening 225 by removing a portion of the second material 222. The portions of the second material 222 may be removed by one or more conventional etch processes, such as a conventional dry etch process. A portion of the first material 220 may be removed by the conventional etch process, or the first material 220 may act as an etch stop for the conventional etch process and may not be removed. The width W₁ of the opening 225 may correspond to a width of the first step 185 of the stepped pillar region 101 in electronic device 100 (FIG. 1A).

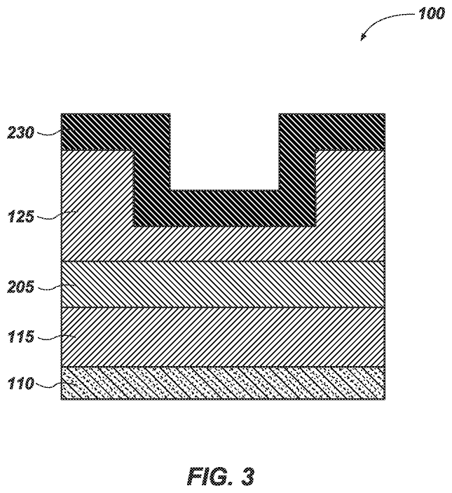

The patterned mask material 210 may be removed and a spacer 230 formed on exposed surfaces of the top semiconductive material 125 in opening 215, as shown in FIG. 3. The spacer 230 may be conformally formed by conventional techniques. The spacer 230 may be formed of and include an oxide material or a nitride material. In some embodiments, the spacer 230 is silicon oxide (SiO₂). The spacer 230 may be formed, for example, at a thickness of from about 1 nm to about 20 nm, such as from about 5 nm to about 20 nm, from about 5 nm to about 15 nm, or from about 10 nm to about 20 nm. A width W2 between the spacers 230 may correspond to a width of the second step 195 of the stepped pillar region 101 in electronic device 100 (FIG. 1A).

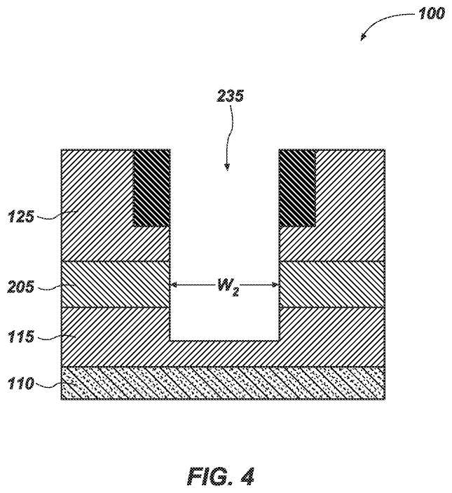

Portions of the spacer 230 may be removed from horizontal surfaces of the top semiconductive material 125, such as from the top surface of the top semiconductive material 125 and from the bottom surface of the opening 215. The portions of the spacer 230 may be removed by one or more conventional etch processes, such as a conventional dry etch process. The spacers 230 remain on vertical surfaces of the top semiconductive material 125 and may be used as a mask. A second opening 235 may be formed by removing a portion of the top semiconductive material 125, a portion of the source contact sacrificial material 205, and a portion of the bottom semiconductive material 115 through the mask, as shown in FIG. 4. The portions of the top semiconductive material 125, the source contact sacrificial material 205, and the bottom semiconductive material 115 may be removed by one or more conventional etch processes, such as a conventional dry etch process. Sidewalls of the top semiconductive material 125, the source contact sacrificial material 205, and the bottom semiconductive material 115 defining the second opening 235 may be spaced apart by the width W2 stepped pillar region 101. The width W2 of the second opening 235 may range from about 25 nm to about 75 nm, such as from about 35 nm to about 65 nm, from about 45 nm to about 55 nm, from about 45 nm to about 65 nm, or from about 45 nm to about 55 nm.

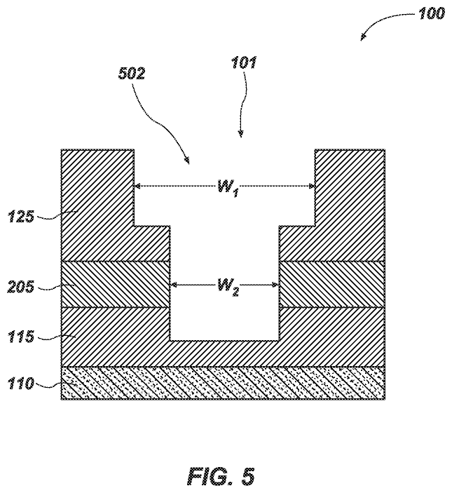

As shown in FIG. 5, the remaining portions of the spacer 230 are removed from the sidewalls of the top semiconductive material 125 to form a stepped opening 502 in which the stepped pillar region 101 of the electronic device 100 (FIG. 1A) is subsequently formed. The remaining portions of the spacer 230 may be removed by one or more conventional etch processes, such as a conventional wet etch process. The stepped opening 502 is defined by sidewalls of the top semiconductive material 125, the source contact sacrificial material 205, and the bottom semiconductive material 115.

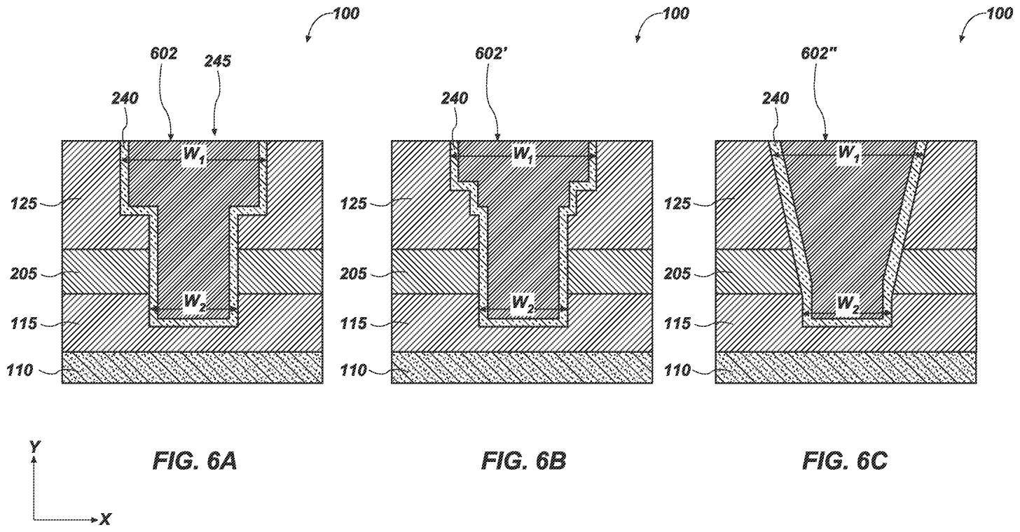

As shown in FIGS. 6A-6C, a liner 240 may be formed on the sidewalls of the stepped opening 502. The liner 240 may be conformally formed by conventional techniques, such as conventional deposition techniques. The liner 240 may be formed of and include an oxide material or a nitride material. In some embodiments, the liner 240 is silicon oxide (SiO₂). The liner 240 may be formed at a thickness of from about 2 nm to about 10 nm. After formation of the liner 240, the stepped opening 502 may be filled with an other conductive material 245, forming a sacrificial structure 602. The other conductive material 245 may be formed by conventional techniques, such as conventional deposition techniques. The other conductive material 245 may include a metal. In some embodiments, the other conductive material 245 is tungsten. The sacrificial structure 602 advantageously acts as an etch stop during formation of the pillars 145, before the first step 185 of the stepped pillar region 101 is formed. Additionally, the sacrificial structure 602 facilities the formation of a thicker channel material 165 in the lateral contact region 199 than in the cell region 142.

FIGS. 6A-6C show embodiments of the sacrificial structure 602 of the electronic device 100. As shown in FIG. 6A, the sacrificial structure 602 includes two substantially rectangular portions configured in a T-shape. A top rectangular portion is larger in the X-direction (e.g., width) than in the Y-direction (e.g., height). The top rectangular portion is adjacent to (e.g., above) a bottom rectangular portion. The bottom rectangular portion differs from the top rectangular portion in that the bottom rectangular portion is larger in the Y-direction than in the X-direction. The top rectangular portion corresponds to the first step 185 of the stepped pillar region 101, while the bottom rectangular portion corresponds to the second step 195 of the stepped pillar region 101. Sidewalls of the top semiconductive material 125 include one step, as shown in FIGS. 6A and 6C.

FIG. 6B shows another embodiment of the sacrificial structure 602′ where the sidewalls of the top semiconductive material 125 include two or more steps. The sacrificial structure 602′ of FIG. 6B is similar to the sacrificial structure 602 of FIG. 6A, with the difference being including one or more additional rectangular portions between the bottom rectangular portion and the top rectangular portion, resulting in additional step(s) as shown in FIG. 6B. The sacrificial structure 602′ may be formed by conducting one or more additional spacer 230 deposition acts on sidewalls of the top semiconductive material 125 and one or more removal acts of portions of the top semiconductive material 125 relative to the process shown in FIGS. 3-5.

The sacrificial structure 602″ of FIG. 6C differs from both the sacrificial structures 602, 602′ of FIG. 6A and FIG. 6B, with the difference being the sacrificial structure 602″ of FIG. 6C has sloped sidewalls (e.g., sidewalls of the top semiconductive material 125 are sloped) and an overall Y-shape. The width of the top of the sacrificial structure 602″ is greater than the width of the bottom of the sacrificial structure 602″. The sacrificial structure 602″ may be formed if removal conditions for the spacer 230 result in sloped sidewalls of the top semiconductive material 125 rather than the top semiconductive material 125 exhibiting substantially vertical sidewalls as shown in the process of FIGS. 3-5. While FIGS. 1A and 1B illustrate sidewalls of the stepped pillar region 101 as being substantially vertical, the sidewalls may be sloped (e.g., tapered). Additionally, while FIGS. 1A and 1B illustrate the electronic device 100 as including a stepped pillar region 101 corresponding to the profile of the sacrificial structure 602′ in FIG. 6B, in other embodiments the electronic device 100 has a stepped pillar region 101 corresponding to the respective profile of the sacrificial structure 602, 602″ in FIG. 6A or 6C.

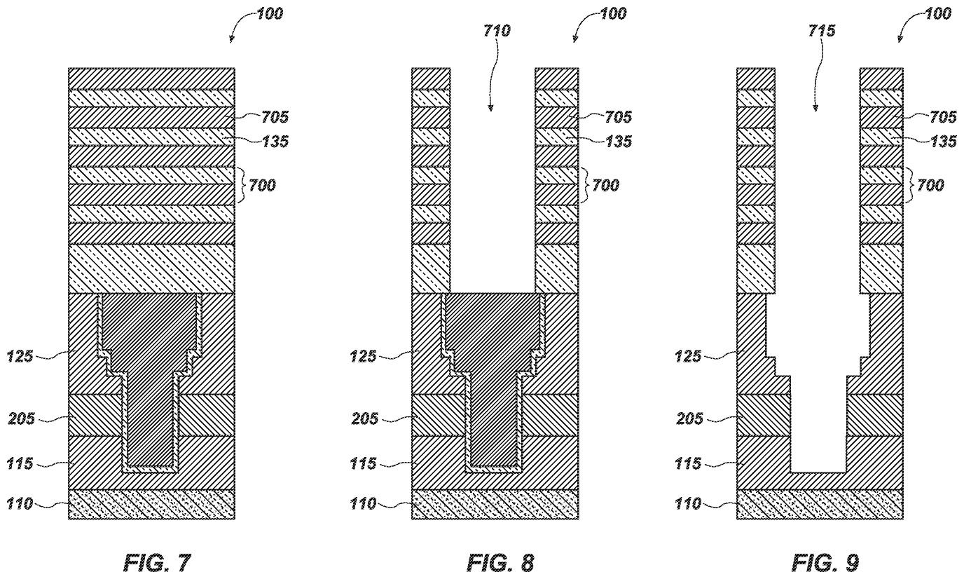

After forming the sacrificial structure 602, 602′, 602″, tiers 700 of alternating nitride materials 705 and insulative materials 135 are formed adjacent to (e.g., on) the top semiconductive material 125, the liner 240, and the other conductive material 245, as shown in FIG. 7. The tiers 700 may be formed by conventional techniques. FIGS. 7-10C show additional process acts conducted after forming the sacrificial structure 602′ of FIG. 6B. However, similar processes acts may be conducted after forming the sacrificial structure 602, 602″ of FIG. 6A or 6C to form electronic devices similar to electronic device 100 except having the stepped pillar region 101 corresponding to the profile shown in FIG. 6A or 6C.

A slit 710 is formed through the tiers 700, exposing sidewalls of the alternating nitride materials 705 and insulative materials 135, and exposing the top surface of the other conductive material 245, as shown in FIG. 8. The slit 710 may be formed by conventional techniques, such as by conventional photolithography and removal processes. The sacrificial structure 602, 602′, 602″ may function as an etch stop during the removal of the portion of the tiers 700 to form the slit 710. The other conductive material 245 and the liner 240 of the sacrificial structure 602, 602′, 602″ may be removed by one or more conventional etch processes, such as a conventional wet etch process to form a pillar opening 715, as shown in FIG. 9. Removal of the other conductive material 245 and the liner 240 exposes sidewalls of the top semiconductive material 125, the source contact sacrificial material 205, and the bottom semiconductive material 115. The pillar opening 715 extends through the tiers 700, the top semiconductive material 125, the source contact sacrificial material 205, and into the bottom semiconductive material 115.

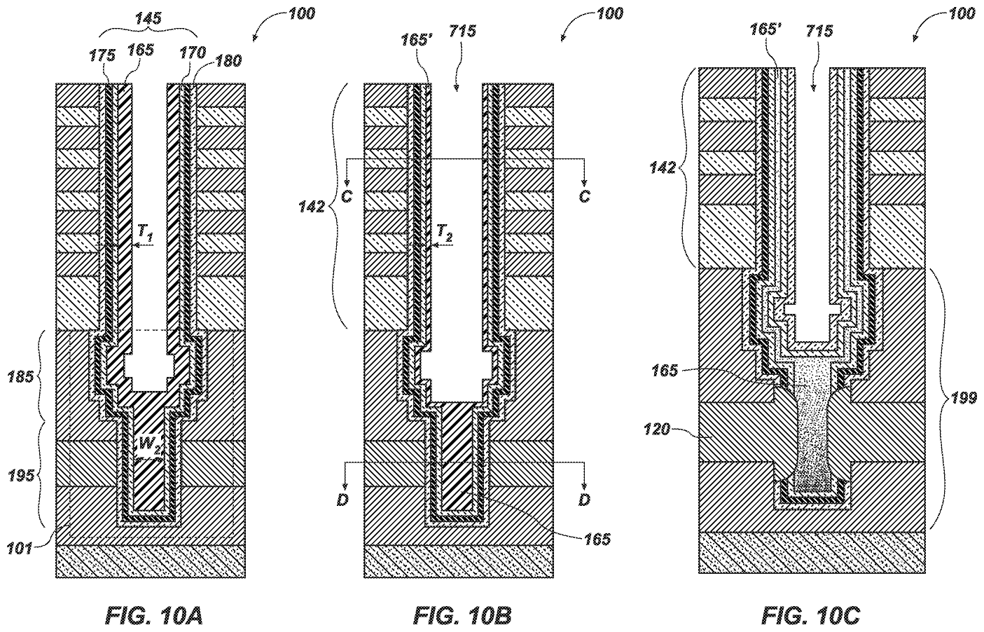

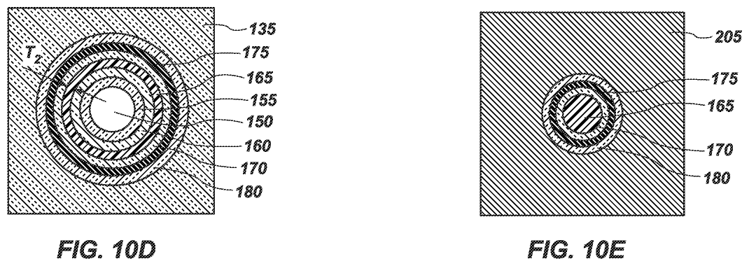

FIGS. 10A-10C show the formation of cell films of the pillars 145 of electronic device 100. The cell films of the pillars 145 are formed in the pillar opening 715, as shown in FIG. 10A. The charge blocking material 180, the charge trap material 175, the tunnel dielectric material 170, and the channel material 165 may be conformally formed in the pillar opening 715 by conventional techniques.

The charge blocking material 180 may be formed of and include a dielectric material. By way of example only, the charge blocking material 180 may be one or more of an oxide (e.g., silicon dioxide), a nitride (e.g., silicon nitride), and an oxynitride (e.g., silicon oxynitride), or another material. In some embodiments, the charge blocking material 180 is silicon dioxide.

The charge trap material 175 may be formed of and include at least one memory material and/or one or more conductive materials. The charge trap material 175 may be formed of and include one or more of silicon nitride, silicon oxynitride, polysilicon (e.g., doped polysilicon), a conductive material (e.g., tungsten, molybdenum, tantalum, titanium, platinum, ruthenium, and alloys thereof, or a metal silicide such as tungsten silicide, molybdenum silicide, tantalum silicide, titanium silicide, nickel silicide, cobalt silicide, or a combination thereof), a semiconductive material (e.g., polycrystalline or amorphous semiconductor material, including at least one elemental semiconductor element and/or including at least one compound semiconductor material, such as conductive nanoparticles (e.g., ruthenium nanoparticles) and/or metal dots). In some embodiments, the charge trap material 175 is silicon nitride.

The tunnel dielectric material 170 may include one or more dielectric materials, such as one or more of a silicon nitride material or a silicon oxide material. In some embodiments, the tunnel dielectric material 170 is a so-called “ONO” structure that includes silicon dioxide, silicon nitride, and silicon dioxide.

The channel material 165 may be formed of and include a semiconductive material, a non-silicon channel material, or other channel material. The material of the channel may include, but is not limited to, a polysilicon material (e.g., polycrystalline silicon), a III-V compound semiconductive material, a II-VI compound semiconductive material, an organic semiconductive material, GaAs, InP, GaP, GaN, an oxide semiconductive material, or a combination thereof.

In some embodiments, the channel material 165 is polysilicon, such as a doped polysilicon. The channel material 165 may be formed by CVD, PVD, or ALD. The channel material 165 may be configured as a so-called doped hollow channel (DHC). However, other channel configurations are possible. A thickness T₁ of the channel material 165 may be from about 10 nm to about 15 nm. In some embodiments, the thickness T₁ of the channel material 165 is about 15 nm. The channel material 165 may substantially fill the second step 195 and a portion of the first step 185 of the stepped pillar region 101, as shown in FIG. 10A. The channel material 165 extending between opposing vertical surfaces of the tunnel dielectric material 170 in the second step 195 has a width W2, which corresponds to two times the thickness T₁ at which the channel material 165 is formed. The portion of the channel material 165 in the second step 195 may, optionally, exhibit a seam (not shown). The channel material 165 may partially fill an upper portion of the pillar opening 715, such as laterally adjacent to the tiers 700.

A portion of the channel material 165 may be removed (e.g., thinned) from the pillars 145 in the cell region 142 and in the first step 185 of the stepped pillar region 101, as shown in FIG. 10B. The portions of the channel material 165 may be removed by one or more conventional etch processes, such as a conventional wet etch process (e.g., a wet cut process). A portion of the channel material 165′ in the cell region 142 and in the first step 185 of the stepped pillar region 101 may be thinner than the remaining portion of the channel material 165 in the second step 195 of the stepped pillar region 101. A thickness T₂ of the thinned portion of the channel material 165′ may be from about 5 nm to about 10 nm. The channel material 165 remains in the second step 195 and may substantially fill the second step 195 of the stepped pillar region 101, as shown in FIG. 10B. The remaining thickness of the portion of the channel material 165′ may be sufficient to protect the charge blocking material 180, the charge trap material 175, and the tunnel dielectric material 170 from etch conditions used during subsequent removal of the source contact sacrificial material 205.

After removing a portion of the channel material 165, an oxidation material 160 may form on the surface of the remaining portion of the channel material 165′, as shown in FIG. 10C. The oxidation material 160, if present, may be formed as a result of a reaction between the material of the portion of the channel material 165′ and the atmosphere (e.g., oxygen gas, O2).

The oxide material 155 may be conformally formed adjacent to (e.g., over) the oxidation material 160 in the pillar opening 715 by conventional techniques. The oxide material 155 may be formed of and include one or more of an oxide (e.g., silicon dioxide) or another material.

The fill material 150 may be formed of and include one or more dielectric materials, such as one or more of a silicon nitride material or a silicon oxide material. In some embodiments, the fill material 150 is silicon dioxide. The fill material 150 may be formed adjacent to the oxide material 155 in the pillar opening 715 by conventional techniques. The fill material 150 may substantially (e.g., completely) fill the pillar opening 715.

The source contact sacrificial material 205 of FIG. 10B may be removed by conventional techniques to form a lateral opening that provides lateral access to the pillars 145, as shown in FIG. 10C. The source contact sacrificial material 205 may be selectively removed, without removing the top semiconductive material 125 and the bottom semiconductive material 115. The portions of the cell films, such as portions of the charge blocking material 180, the charge trap material 175, and the tunnel dielectric material 170 proximal to the source contact sacrificial material 205 may also be removed, exposing sidewalls of the channel material 165 in the first step 185 and second step 195. The channel material 165 proximal to the source contact sacrificial material 205 may be of sufficient thickness to protect the cell films laterally adjacent to the tiers 700 from the etch conditions used to remove the source contact sacrificial material 205 and the portions of the charge blocking material 180, the charge trap material 175, and the tunnel dielectric material 170. The channel material 165′ in the second step 195, which has the width W2, may prevent the formation of pinholes through the channel material 165 during the removal of the source contact sacrificial material 205 and the portions of the charge blocking material 180, the charge trap material 175, and the tunnel dielectric material 170 proximal to the source contact sacrificial material 205. Such pinholes, if present, may lead to damage to the channel material 165 laterally adjacent to the tiers 700. Depending on the etch chemistry used, surfaces of the channel material 165, the charge blocking material 180, the charge trap material 175, and the tunnel dielectric material 170 defining the lateral opening may be substantially linear (not shown) or may be curved. The source contact 120 is subsequently formed in the lateral opening. By way of non-limiting example, the source contact 120 may be formed of a doped polysilicon, such as phosphorus doped polysilicon. As indicated in FIG. 10C by the gradient of shading, the dopant, such as phosphorus, may diffuse from the source contact 120 and into the channel material 165 by a diffusion method, such as solid state diffusion. The dopant concentration of the channel material 165 in the lateral contact region 199 may be greater than the dopant concentration of the portion of the channel material 165′ in the cell region 142.

Subsequent process acts are then conducted to the structure of FIG. 10C to form the electronic device 100 shown in FIG. 1A. The subsequent process acts are conducted by conventional techniques. By way of example only, a replacement gate process is conducted to remove the nitride materials 705 of the tiers 700 and to form the conductive materials 140 of the tiers 130. The nitride materials 705 may be removed by exposing the tiers 700 to a wet etch chemistry formulated to remove, for example, silicon nitride. The wet etchant may include, but is not limited to, one or more of phosphoric acid, sulfuric acid, hydrochloric acid, nitric acid, or a combination thereof. In some embodiments, the nitride materials 705 of the tiers 700 are removed using a so-called “wet nitride strip” that includes phosphoric acid.

FIGS. 10D and 10E are top-down views of an electronic device, in accordance with embodiments of the disclosure. FIG. 10D shows a top-down view of the electronic device 100 along line C-C of FIG. 10B. Line C-C is a cross-sectional cut through the insulative material 135 and the memory cell 144 in the memory cell region 142. FIG. 10E shows a top-down view of the electronic device 100 along line D-D of FIG. 10B. Line D-D is a cross-sectional cut through at least the source contact sacrificial material 205 and the channel material 165 in the lateral contact region 199. With combined reference to FIGS. 10D and 10E, the thickness of the channel material 165 in the memory cell region 142 (FIG. 10D) is relatively thinner than the thickness of the channel material 165 in the lateral contact region 199 (FIG. 10E).

The electronic device 100 includes the channel material 165 having portions of different thicknesses, with a reduced thickness proximal to the cell region 142 and a greater thickness proximal to the lateral contact region 199. By forming the channel material 165 at an initial thickness and then removing a portion of the channel material 165 so that the channel material 165′ has a desired, smaller thickness, the electronic device 100 including the channel material 165′ may exhibit improved electrical performance. The reduced thickness of the channel material 165′ laterally adjacent to the tiers 130 enables the improved electrical performance of the electronic device 100. However, the thicker channel material 165 proximal to the source contact 120 and the second step 195 may be sufficient to protect the charge blocking material 180, the charge trap material 175, and the tunnel dielectric material 170 from damage during fabrication. Therefore, the improved electrical performance of the electronic device 100 may be achieved while the channel material 165′ also provides protection during subsequent processing acts.

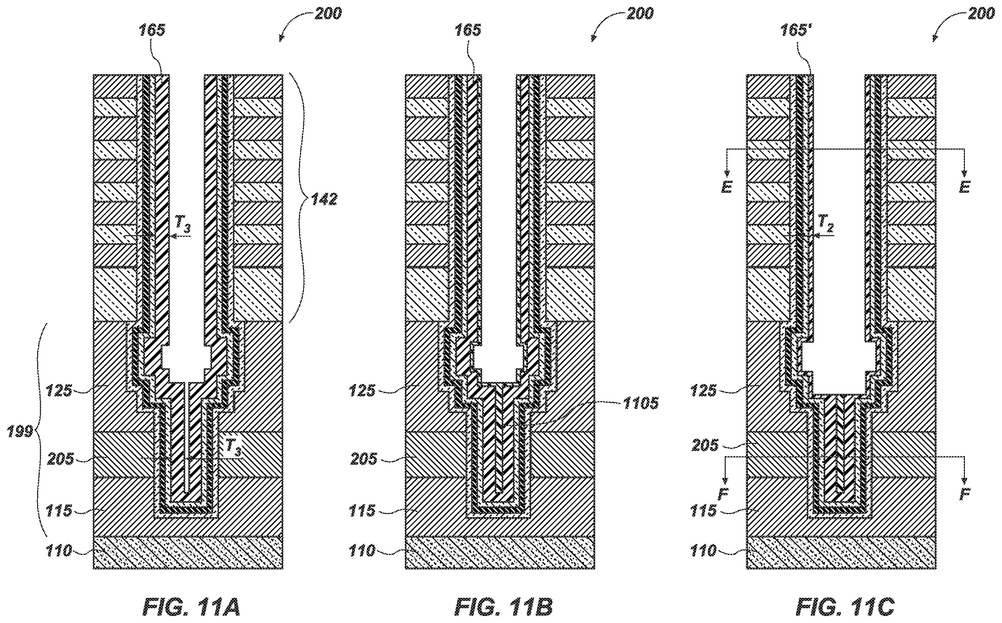

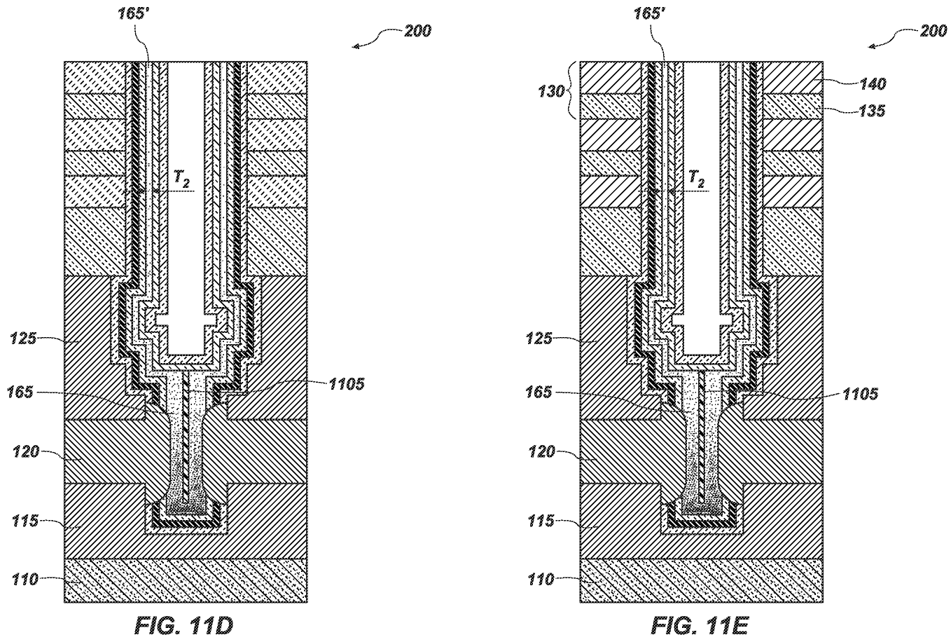

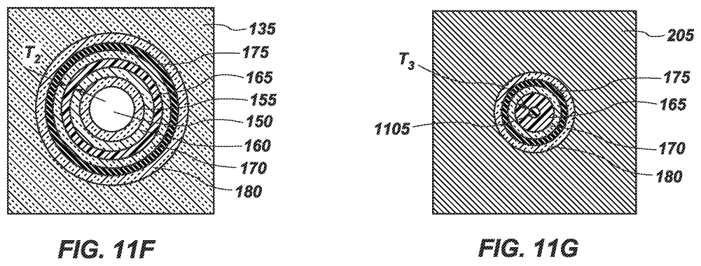

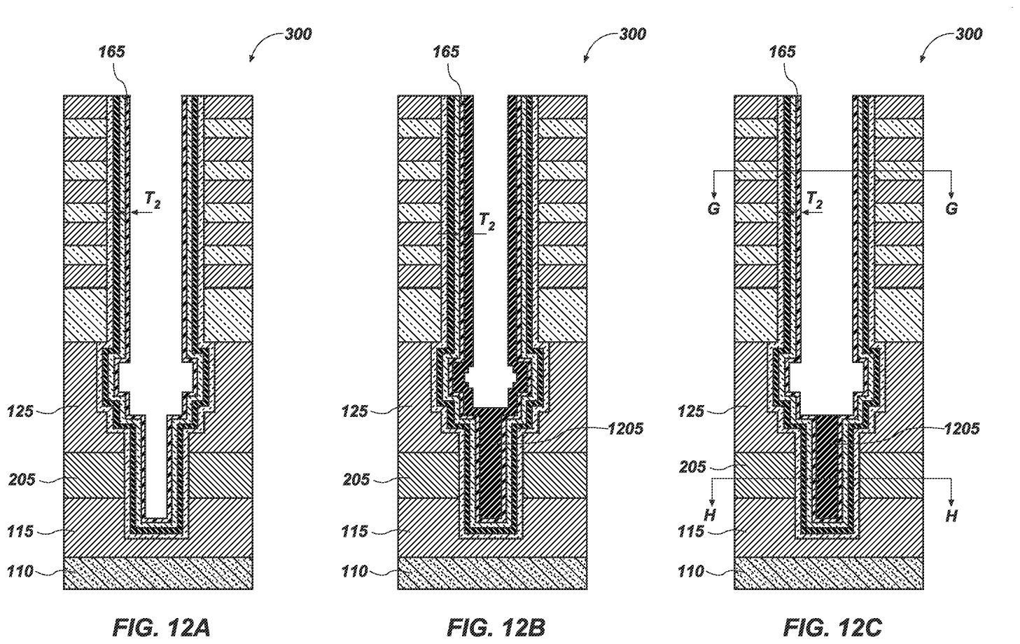

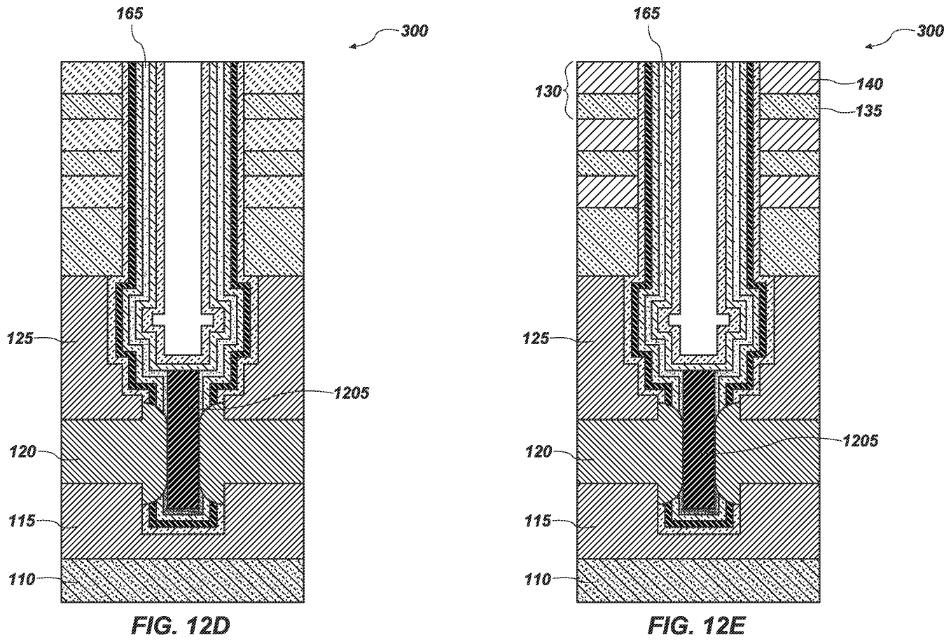

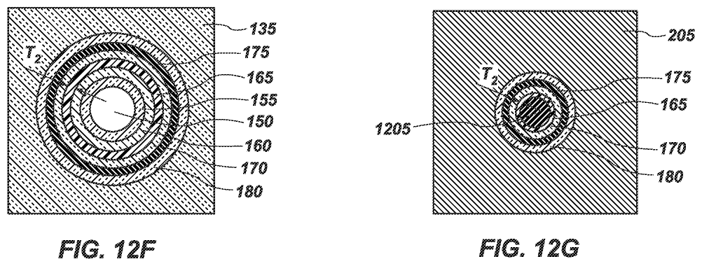

FIGS. 11A-11E, and 12A-12E show additional embodiments of electronic devices 200, 300 including the stepped pillar region 101 and the channel material 165 that are similar to the electronic device 100. In addition, the methods shown in FIGS. 11A-11E, and 12A-12E are similar to the methods of forming the electronic device 100. Specifically, the method acts described above with reference to FIGS. 2A-9 are used to form electronic device 200, as shown in FIGS. 11A-11D. The electronic device 200 of FIG. 11A is similar to electronic device 100 of FIG. 10A, with the difference being a thickness T₃ of the channel material 165 as initially formed, and the remaining thickness T₂ of the channel material 165 in the second step 195 of stepped pillar region 101. The method of forming the electronic device 200 may otherwise be similar to the method of forming electronic device 100 described above. Only method acts that differ substantially from the method of forming the electronic device 100 are described.

After forming the pillar opening 715 (FIG. 9) as described above, the charge blocking material 180, the charge trap material 175, and the tunnel dielectric material 170 may be conformally formed in the pillar opening 715 by conventional techniques. After forming the tunnel dielectric material 170, the channel material 165 may be conformally formed along the sidewalls of the tunnel dielectric material 170, as shown in FIG. 11A, to partially fill the pillar opening 715. The thickness T₃ of the channel material 165 may be from about 10 nm to about 15 nm. In some embodiments, the thickness T₃ of the channel material 165 is about 15 nm. However, the thickness T₃ of the channel material 165 as initially formed may be greater than the ranges above as long as a sufficient portion of the pillar opening 715 remains unfilled and able to contain additional materials as described below. If the initially formed thickness is too large, a wet etch process may subsequently be conducted to remove excess channel material 165 to achieve the thickness T₃. The thickness T₃ of the channel material 165 may be substantially the same in the cell region 142 and in the lateral contact region 199. The channel material 165 may fill a portion of the second step 195 and a portion of the first step 185 of the stepped pillar region 101, as shown in FIG. 11A. In some embodiments, an air gap may exist within the second step 195 and adjacent to (e.g., between) portions of the channel material 165.

A fill material 1105 may be formed adjacent to the channel material 165 of the electronic device 200 by conventional techniques, as shown in FIG. 11B. The fill material 1105 may be formed of and include one or more of oxide materials or doped polysilicon. The fill material 1105 and the channel material 165 may substantially (e.g., completely) fill the second step 195 of the stepped pillar region 101 and partially fill the first step 185 of the stepped pillar region 101.

A portion of the fill material 1105 and the channel material 165 is substantially removed (e.g., completely removed) from the tiers 700 in the cell region 142 and in the first step 185 of the stepped pillar region 101, as shown in FIG. 11C. The desired portions may be removed by one or more etch processes. The portions of the fill material 1105 may, for example, be removed by one or more conventional etch processes, such as oxide etching, while the portions of the channel material 165 may be removed by one or more wet etch processes. The portion of the fill material 1105 may be completely removed from the cell region 142 and from the sidewalls of the first step 185 of the stepped pillar region 101. The portion of the channel material 165 remaining in the cell region 142 and in the first step 185 of the stepped pillar region 101 may be thinner than the remaining portion of the channel material 165 in the second step 195 of the stepped pillar region 101. The thickness T₂ of the thinned portion of the channel material 165 may be from about 5 nm to about 10 nm. After removing a portion of the channel material 165, the channel material 165 remains in the second step 195. A combination of the channel material 165 and the fill material 1105 may substantially fill the second step 195 of the stepped pillar region 101, as shown in FIG. 11C, with the channel material 165 being thicker in the second step 195 than in the first step 185.

Subsequent process acts are then conducted to form the electronic device 200, as shown in FIGS. 11D and 11E and as described above for FIG. 10C. The electronic device 200 may include the oxidation material 160 and the oxide material 155. The source contact sacrificial material 205 is removed and replaced with the source contact 120. The replacement gate process is conducted to remove the nitride materials 705 of the tiers 700 and to form the conductive materials 140 of the tiers 130. By including the fill material 1105 in the lateral contact region 199, between opposing portions of the channel material 165, cracking of the channel material 164, other cell films, the top semiconductive material 125, and the bottom semiconductive material 115 may be reduced. The fill material 1105 may also reduce cracking associated with crystallization of amorphous silicon. The reduced cracking may improve (e.g., increase) string current of the electronic device 200.

FIGS. 11F and 11G are top-down views of an electronic device, in accordance with embodiments of the disclosure. FIG. 11F shows a top-down view of the electronic device 200 along line E-E of FIG. 11C. Line E-E is a cross-sectional cut through the insulative material 135 and the memory cell 144 in the memory cell region 142. FIG. 11F shows the thickness T₂ of the thinned portion of the channel material 165 in the memory cell region 142.

FIG. 11G shows a top-down view of the electronic device 200 along line F-F of FIG. 11C. Line D-D is a cross-sectional cut through at least the source contact sacrificial material 205 and the channel material 165 in the lateral contact region 199. FIG. 11G shows the thickness T₃ of the channel material 165 in the lateral contact region 199. With combined reference to FIGS. 11F and 11G, the thickness of the channel material 165 in the memory cell region 142 (FIG. 11F) is relatively thinner than the thickness of the channel material 165 in the lateral contact region 199 (FIG. 11G).

The electronic device 300 shown FIGS. 12A-12E is similar to electronic device 200 of FIG. 11A, with the difference being the channel material 165 is formed at a desired thickness T₂ rather than being thinned to a desired thickness. The method of forming the electronic device 300 may otherwise be similar to the method of forming the electronic devices 100, 200. Only method acts and details that differ substantially from the method of forming the electronic devices 100, 200 are described.

After forming the pillar opening 715 (FIG. 9) as described above, the charge blocking material 180, the charge trap material 175, and the tunnel dielectric material 170 may be conformally formed in the pillar opening 715 by conventional techniques. After forming the tunnel dielectric material 170, the channel material 165 may be conformally formed along the sidewalls of the tunnel dielectric material 170, as shown in FIG. 12A. The thickness T₂ of the channel material 165 may be from about 5 nm to about 10 nm. In some embodiments, the thickness T₂ of the channel material 165 is about 5 nm. The thickness T₂ of the channel material 165 may be substantially the same in the cell region 142 and in the lateral contact region 199. The channel material 165 may fill a portion of the second step 195 and a portion of the first step 185 of the stepped pillar region 101, as shown in FIG. 12A. An air gap may exist within the second step 195 and adjacent to (e.g., between) portions of the channel material 165.

Another fill material 1205 may be formed adjacent to the channel material 165 of electronic device 300 by conventional techniques, as shown in FIG. 12B. The other fill material 1205 may be formed of and include one or more of an oxide material or doped polysilicon, such as arsenic doped polysilicon, phosphorus doped polysilicon, or arsenic and phosphorus doped polysilicon. The other fill material 1205 may substantially (e.g., completely) fill the second step 195 of the stepped pillar region 101 and partially fill the first step 185. The other fill material 1205 may be selectively etchable relative to other materials of the electronic device 300, specifically the channel material 165.

A portion of the other fill material 1205 may be substantially removed (e.g., completely removed) from the tiers 700 in the cell region 142 and in the first step 185 of the stepped pillar region 101, as shown in FIG. 12C. The portions of the other fill material 1205 may be removed by one or more conventional etch processes, such as a conventional wet etch process. The channel material 165 and the other fill material 1205 may substantially fill the second step 195 of the stepped pillar region 101, as shown in FIG. 12C.

Subsequent process acts are then conducted to form the electronic device 300, as shown in FIGS. 12D and 12E. The electronic device 300 includes the oxidation material 160 and the oxide material 155. The source contact sacrificial material 205 is removed and replaced with source contact 120. The replacement gate process is conducted to remove the nitride materials 705 of the tiers 700 and to form the conductive materials 140 of the tiers 130.

FIGS. 12F and 12G are top-down views of an electronic device, in accordance with embodiments of the disclosure. FIG. 12F shows a top-down view of the electronic device 300 along line G-G of FIG. 12C. Line H-H is a cross-sectional cut through the insulative material 135 and the memory cell 144 in the memory cell region 142. FIG. 12G shows a top-down view of the electronic device 300 along line H-H of FIG. 12C. Line H-H is a cross-sectional cut through at least the source contact sacrificial material 205 and the channel material 165 in the lateral contact region 199. With combined reference to FIGS. 12F and 12G, the thickness of the channel material 165 in the memory cell region 142 (FIG. 12F) is substantially the same as the thickness of the channel material 165 in the lateral contact region 199 (FIG. 12G).

One or more electronic devices 100, 200, 300 according to embodiments of the disclosure may be present in an apparatus or in an electronic system. The electronic device 100, 200, 300, the apparatus including the one or more electronic device 100, 200, 300, or the electronic system including the one or more electronic device 100, 200, 300 may include additional components, which are formed by conventional techniques. The additional components may include, but are not limited to, staircase structures, interdeck structures, contacts, interconnects, data lines (e.g., bit lines), access lines (e.g., word lines), etc. The additional components may be formed during the fabrication of the electronic device 100, 200, 300 or after the electronic device 100, 200, 300 has been fabricated. By way of example only, one or more of the additional components may be formed before or after the cell films of the pillars 145 are formed, while other additional components may be formed after the electronic device 100, 200, 300 has been fabricated. The additional components may be present in locations of the electronic device 100, 200, 300 or the apparatus that are not depicted in the perspectives of FIGS. 1-12E.

The electronic device 100, 200, 300, and methods according to embodiments of the disclosure advantageously prevent dopant diffusion into the cell region 142. During use and operation of the electronic device 100, 200, 300, the thickness of channel material 165 in the cell region 142 facilitates good cell characteristics, such as cell reliability, while the thickness of the channel material 165 in the lateral contact region 199 prevents damage to the channel material 165.

Accordingly, disclosed is an electronic device comprising memory pillars and a source contact. The memory pillars comprise a channel material and extend through both a cell region and a lateral contact region. A portion of the memory pillars in the lateral contact region comprises at least one first step and at least one second step. The source contact is in direct contact with the channel material in the at least one second step of the portion of the memory pillars in the lateral contact region.

Accordingly, disclosed is an electronic device comprising a bottom semiconductive material, a source contact adjacent to the bottom semiconductive material, a top semiconductive material adjacent to the source contact, tiers of alternating conductive materials and dielectric materials adjacent to the top semiconductive material, and pillars extending through the tiers, the top semiconductive material, and the source contact and into the bottom semiconductive material. The pillars comprise a channel material, wherein a thickness of the channel material laterally adjacent to the tiers is less than the thickness of the channel material laterally adjacent to the source contact.

Accordingly, disclosed is a method of forming an electronic device comprising forming a bottom semiconductive material. A source contact sacrificial material is formed adjacent to the bottom semiconductor material. A top semiconductive material is formed adjacent to the source contact sacrificial material. A portion of the bottom semiconductive material, a portion of the source contact sacrificial material, and a portion of the top semiconductive material are removed to form stepped openings. A sacrificial structure is formed in the stepped openings. Tiers are formed adjacent to the top semiconductive material and the sacrificial structure. Pillar openings are formed through the tiers. The sacrificial structure is removed from the stepped openings to form a stepped feature region. Cell films comprising a channel material are formed in the pillar openings and the stepped feature region. A portion of the channel material is removed from the pillar openings. The source contact sacrificial material is selectively removed to form a source contact opening. A source contact is formed in the source contact opening extending laterally and contacting the channel material.

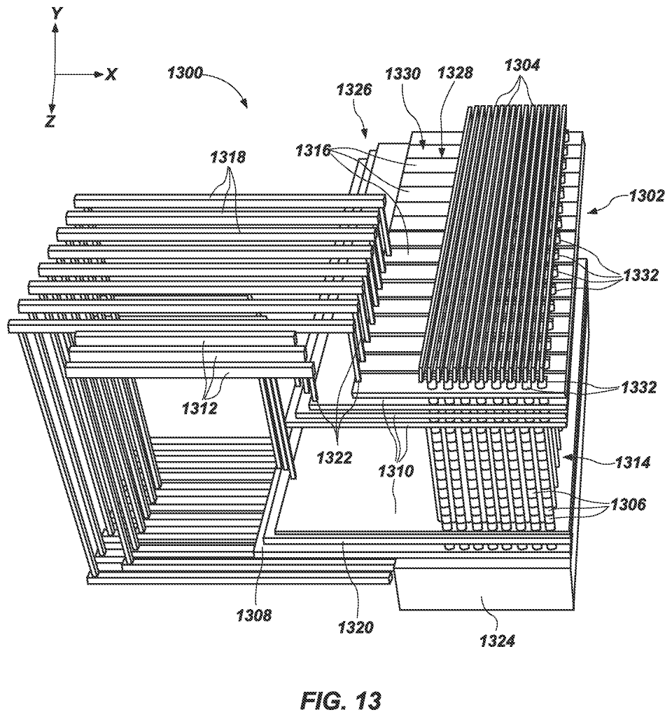

With reference to FIG. 13 illustrated is a partial cutaway, perspective, schematic illustration of a portion of an apparatus 1300 (e.g., a memory device) including an electronic device 1302 according to embodiments of the disclosure. The electronic device 1302 may be substantially similar to the embodiments of the electronic device described above (e.g., the electronic device 100, 200, 300) and may have been formed by the methods described above. By way of example only, the memory device may be a 3D NAND Flash memory device, such as a multideck 3D NAND Flash memory device. As illustrated in FIG. 13, the electronic device 1302 may include a staircase structure 1326 defining contact regions for connecting access lines (e.g., word lines) 1312 to conductive tiers 1310 (e.g., conductive layers, conductive materials of tiers). The electronic device 1302 may include pillars 145 (see FIGS. 1A, 11E, 12E) with strings 1314 (e.g., strings of memory cells) that are coupled to each other in series. The pillars 145 with the strings 1314 may extend at least somewhat vertically (e.g., in the Z-direction) and orthogonally relative to the conductive tiers 1310, relative to data lines 1304, relative to a source tier 1308, relative to the access lines 1312, relative to first select gates 1316 (e.g., upper select gates, drain select gates (SGDs), relative to select lines 1318, and/or relative to second select gates 1320. The first select gates 1316 may be horizontally divided (e.g., in the X-direction) into multiple blocks 1330 by slits 1328.

Vertical conductive contacts 1322 may electrically couple components to each other, as illustrated. For example, the select lines 1318 may be electrically coupled to the first select gates 1316, and the access lines 1312 may be electrically coupled to the conductive tiers 1310. The apparatus 1300 may also include a control unit 1324 positioned under the memory array, which may include at least one of string driver circuitry, pass gates, circuitry for selecting gates, circuitry for selecting conductive lines (e.g., the data lines 1304, the access lines 1312), circuitry for amplifying signals, and circuitry for sensing signals. The control unit 1324 may be electrically coupled to the data lines 1304, the source tier 1308, the access lines 1312, the first select gates 1316, and/or the second select gates 1320, for example. In some embodiments, the control unit 1324 includes CMOS (complementary metal-oxide-semiconductor) circuitry. In such embodiments, the control unit 1324 may be characterized as having a so-called “CMOS under Array” (CuA) configuration.

The first select gates 1316 may extend horizontally in a first direction (e.g., the Y-direction) and may be coupled to respective first groups of strings 1314 of memory cells 1306 at a first end (e.g., an upper end) of the strings 1314. The second select gate 1320 may be formed in a substantially planar configuration and may be coupled to the strings 1314 at a second, opposite end (e.g., a lower end) of the strings 1314 of memory cells 1306.

The data lines 1304 (e.g., bit lines) may extend horizontally in a second direction (e.g., in the X-direction) that is at an angle (e.g., perpendicular) to the first direction in which the first select gates 1316 extend. The data lines 1304 may be coupled to respective second groups of the strings 1314 at the first end (e.g., the upper end) of the strings 1314. A first group of strings 1314 coupled to a respective first select gate 1316 may share a particular string 1314 with a second group of strings 1314 coupled to a respective data line 1304. Thus, a particular string 1314 may be selected at an intersection of a particular first select gate 1316 and a particular data line 1304. Accordingly, the first select gates 1316 may be used for selecting memory cells 1306 of the strings 1314 of memory cells 1306.

The conductive tiers 1310 (e.g., word lines, conductive materials 110) may extend in respective horizontal planes. The conductive tiers 1310 may be stacked vertically, such that each conductive tier 1310 is coupled to all of the strings 1314 of memory cells 1306, and the strings 1314 of the memory cells 1306 extend vertically through the stack of conductive tiers 1310. The conductive tiers 1310 may be coupled to or may function as control gates of the memory cells 1306 to which the conductive tiers 1310 are coupled. Each conductive tier 1310 may be coupled to one memory cell 1306 of a particular string 1314 of memory cells 1306. The first select gates 1316 and the second select gates 1320 may operate to select a particular string 1314 of the memory cells 1306 between a particular data line 1304 and the source tier 1308. Thus, a particular memory cell 1306 may be selected and electrically coupled to a data line 1304 by operation of (e.g., by selecting) the appropriate first select gate 1316, second select gate 1320, and conductive tier 1310 that are coupled to the particular memory cell 1306.

The staircase structure 1326 may be configured to provide electrical connection between the access lines 1312 and the conductive materials of the tiers 1310 through the vertical conductive contacts 1322. In other words, a particular level of the conductive tiers 1310 may be selected via one of the access lines 1312 that is in electrical communication with a respective one of the vertical conductive contacts 1322 in electrical communication with the particular conductive tier 1310. The data lines 1304 may be electrically coupled to the strings 1314 through conductive structures 1332 (e.g., conductive contacts).

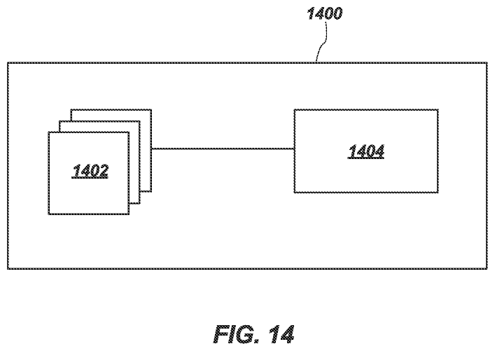

The apparatus 1300 including the electronic devices 100, 200, 300 may be used in embodiments of electronic systems of the disclosure. FIG. 14 is a block diagram of an electronic system 1400, in accordance with embodiments of the disclosure. The electronic system 1400 includes, for example, a computer or computer hardware component, a server or other networking hardware component, a cellular telephone, a digital camera, a personal digital assistant (PDA), a portable media (e.g., music) player, a Wi-Fi or cellular-enabled tablet (e.g., an iPAD® or SURFACE® tablet, an electronic book, a navigation device), etc. The electronic system 1400 includes at least one memory device 1402 that includes, for example, one or more electronic devices 100, 200, 300. The electronic system 1400 may further include at least one electronic signal processor device 1404 (e.g., a microprocessor). The electronic signal processor device 1404 may, optionally, include one or more electronic devices 100, 200, 300.

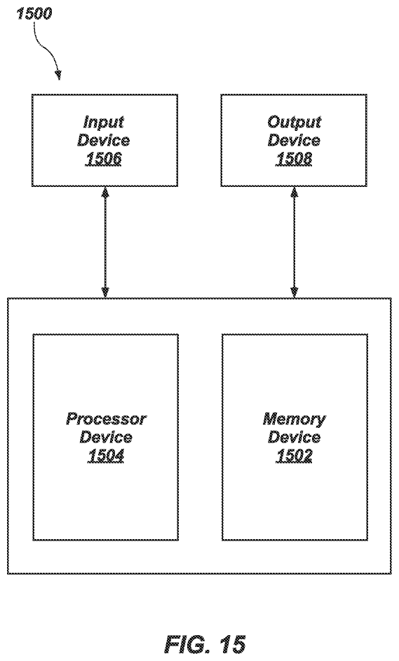

A processor-based system 1500 (e.g., an electronic processor-based system), shown in FIG. 15, includes one or more input devices 1506 for inputting information into the processor-based system 1500 by a user, such as, for example, a mouse or other pointing device, a keyboard, a touchpad, a button, or a control panel. The processor-based system 1500 may further include one or more output devices 1508 for outputting information (e.g., visual or audio output) to a user such as, for example, a monitor, a display, a printer, an audio output jack, a speaker, etc. In some embodiments, the input device 1506 and the output device 1508 may comprise a single touchscreen device that can be used both to input information into the processor-based system 1500 and to output visual information to a user. The input device 1506 and the output device 1508 may communicate electrically with one or more of the memory device 1502 and the electronic signal processor device 1504. The memory device 1502 and the electronic signal processor device 1504 may include one or more of the electronic devices 100.

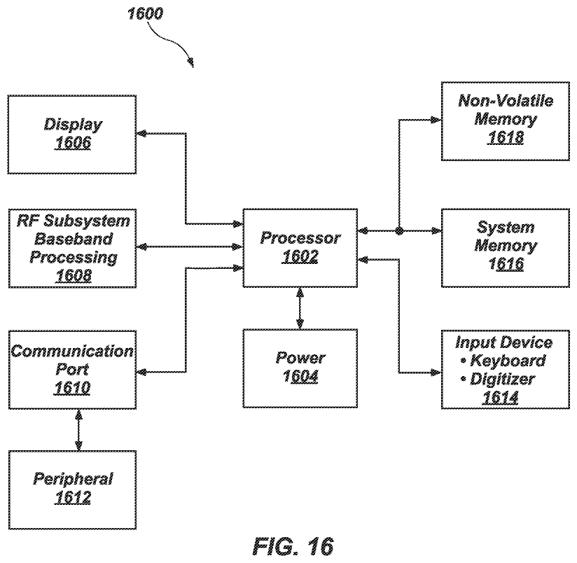

With reference to FIG. 16, shown is a block diagram of an additional processor-based system 1600 (e.g., an electronic processor-based). The processor-based system 1600 may include various electronic devices 100 and apparatus 1300 manufactured in accordance with embodiments of the disclosure. The processor-based system 1600 may be any of a variety of types, such as a computer, a pager, a cellular phone, a personal organizer, a control circuit, or another electronic device. The processor-based system 1600 may include one or more processors 1602, such as a microprocessor, to control the processing of system functions and requests in the processor-based system 1600. The processor 1602 and other subcomponents of the processor-based system 1600 may include electronic devices 100 and apparatus 1300 manufactured in accordance with embodiments of the disclosure.

The processor-based system 1600 may include a power supply 1604 in operable communication with the processor 1602. For example, if the processor-based system 1600 is a portable system, the power supply 1604 may include one or more of a fuel cell, a power scavenging device, permanent batteries, replaceable batteries, and/or rechargeable batteries. The power supply 1604 may also include an AC adapter if, for example, the processor-based system 1600 may be plugged into a wall outlet. The power supply 1604 may also include a DC adapter such that the processor-based system 1600 may be plugged into a vehicle cigarette lighter or a vehicle power port, for example.

Various other devices may be coupled to the processor 1602 depending on the functions that the processor-based system 1600 performs. For example, a user interface may be coupled to the processor 1602. The user interface may include one or more input devices 1614, such as buttons, switches, a keyboard, a light pen, a mouse, a digitizer and stylus, a touch screen, a voice recognition system, a microphone, or a combination thereof. A display 1606 may also be coupled to the processor 1602. The display 1606 may include an LCD display, an SED display, a CRT display, a DLP display, a plasma display, an OLED display, an LED display, a three-dimensional projection, an audio display, or a combination thereof. Furthermore, an RF subsystem/baseband processor 1608 may also be coupled to the processor 1602. The RF subsystem/baseband processor 1608 may include an antenna that is coupled to an RF receiver and to an RF transmitter. A communication port 1610, or more than one communication port 1610, may also be coupled to the processor 1602. The communication port 1610 may be adapted to be coupled to one or more peripheral devices 1612 (e.g., a modem, a printer, a computer, a scanner, a camera) and/or to a network (e.g., a local area network (LAN), a remote area network, an intranet, or the Internet).

The processor 1602 may control the processor-based system 1600 by implementing software programs stored in the memory (e.g., system memory 1616). The software programs may include an operating system, database software, drafting software, word processing software, media editing software, and/or media-playing software, for example. The memory is operably coupled to the processor 1602 to store and facilitate execution of various programs. For example, the processor 1602 may be coupled to system memory 1616, which may include one or more of spin torque transfer magnetic random access memory (STT-MRAM), magnetic random access memory (MRAM), dynamic random access memory (DRAM), static random access memory (SRAM), racetrack memory, and/or other known memory types. The system memory 1616 may include volatile memory, nonvolatile memory, or a combination thereof. The system memory 1616 is typically large so it can store dynamically loaded applications and data. The system memory 1616 may include one or more apparatus 1300 and one or more electronic devices 100, 200, 300 according to embodiments of the disclosure.

The processor 1602 may also be coupled to nonvolatile memory 1618, which is not to suggest that system memory 1616 is necessarily volatile. The nonvolatile memory 1618 may include one or more of STT-MRAM, MRAM, read-only memory (ROM) (e.g., EPROM, resistive read-only memory (RROM)), and Flash memory to be used in conjunction with the system memory 1616. The size of the nonvolatile memory 1618 is typically selected to be just large enough to store any necessary operating system, application programs, and fixed data. Additionally, the nonvolatile memory 1618 may include a high-capacity memory (e.g., disk drive memory, such as a hybrid-drive including resistive memory or other types of nonvolatile solid-state memory, for example). The nonvolatile memory 1618 may include one or more apparatus 1300 and one or more electronic devices 100, 200, 300 according to embodiments of the disclosure.

While certain illustrative embodiments have been described in connection with the figures, those of ordinary skill in the art will recognize and appreciate that embodiments encompassed by the disclosure are not limited to those embodiments explicitly shown and described herein. Rather, many additions, deletions, and modifications to the embodiments described herein may be made without departing from the scope of embodiments encompassed by the disclosure, such as those hereinafter claimed, including legal equivalents. In addition, features from one disclosed embodiment may be combined with features of another disclosed embodiment while still being encompassed within the scope of the disclosure.

What is claimed is:

1. An electronic device, comprising:
memory pillars comprising a channel material and extending through both a cell region and a lateral contact region, a portion of the memory pillars in the lateral contact region comprising:
at least one first step;
at least one second step; and
a source contact in direct contact with the channel material in the at least one second step of the portion of the memory pillars in the lateral contact region.

2. The electronic device of claim 1, wherein the lateral contact region comprises a stepped pillar region.

3. The electronic device of claim 2, wherein the at least one second step of the stepped pillar region in the lateral contact region exhibits a relatively smaller critical dimension than a critical dimension of the at least one first step of the stepped pillar region.

4. The electronic device of claim 2, wherein the at least one second step of the stepped pillar region in the lateral contact region exhibits a relatively smaller critical dimension than a critical dimension of the memory pillars of the cell region.

5. The electronic device of claim 1, wherein the channel material in the lateral contact region substantially fills the at least one second step of the memory pillars.

6. The electronic device of claim 1, further comprising a fill material adjacent to the channel material in the lateral contact region of the memory pillars.

7. The electronic device of claim 6, wherein a thickness of the fill material is less than a thickness of the channel material in the lateral contact region of the memory pillars.

8. The electronic device of claim 6, wherein a thickness of the fill material is greater than a thickness of the channel material in the lateral contact region of the memory pillars.

9. The electronic device of claim 6, wherein a thickness of the channel material in direct contact with the source contact is substantially equal to the thickness of the channel material in the cell region.

10. The electronic device of claim 1, wherein the at least one first step and the at least one second step exhibit sloped sidewalls.

11. The electronic device of claim 1, wherein a portion of the source contact proximal to the memory pillars is wider than a portion of the source contact distal to the memory pillars.

12. The electronic device of claim 1, wherein the channel material extends continuously along an entire height of the memory pillars.

13. The electronic device of claim 1, wherein a thickness of the channel material in direct contact with the source contact is greater than a thickness of the channel material in the cell region.

14. An electronic device, comprising:
a bottom semiconductive material;
a source contact adjacent to the bottom semiconductive material;
a top semiconductive material adjacent to the source contact;
tiers of alternating conductive materials and dielectric materials adjacent to the top semiconductive material; and
pillars extending through the tiers, the top semiconductive material, and the source contact and into the bottom semiconductive material, the pillars comprising:
a channel material, wherein a thickness of the channel material laterally adjacent to the tiers is less than the thickness of the channel material laterally adjacent to the source contact.

15. The electronic device of claim 14, wherein a diameter of a portion of the pillars laterally adjacent to the top semiconductive material is greater than a diameter of a portion of the pillars laterally adjacent to the tiers of alternating conductive materials and dielectric materials.

16. The electronic device of claim 14, wherein a diameter of a portion of the pillars laterally adjacent to the source contact and the bottom semiconductive material is less than the diameter of a portion of the pillars laterally adjacent to the top semiconductive material.

17. The electronic device of claim 14, wherein the channel material comprises a polysilicon material, a III-V compound semiconductive material, a II-VI compound semiconductive material, an organic semiconductive material, GaAs, InP, GaP, GaN, an oxide semiconductive material, or a combination thereof.

18. The electronic device of claim 14, wherein the channel material in a cell region exhibits a different dopant concentration than the channel material in a lateral contact region.

19. A method of forming an electronic device, the method comprising:
forming a bottom semiconductive material;
forming a source contact sacrificial material adjacent to the bottom semiconductive material;
forming a top semiconductive material adjacent to the source contact sacrificial material;
removing a portion of the bottom semiconductive material, a portion of the source contact sacrificial material, and a portion of the top semiconductive material to form stepped openings;
forming a sacrificial structure in the stepped openings;
forming tiers adjacent to the top semiconductive material and the sacrificial structure;
forming pillar openings through the tiers;
removing the sacrificial structure from the stepped openings to form a stepped feature region;
forming cell films in the pillar openings and the stepped feature region, the cell films comprising a channel material;
removing a portion of the channel material in the pillar openings;
selectively removing the source contact sacrificial material to form a source contact opening; and
forming a source contact in the source contact opening extending laterally and contacting the channel material.

20. The method of claim 19, further comprising forming a fill material adjacent to the channel material in the stepped feature region.

21. The method of claim 19, wherein removing a portion of the bottom semiconductive material, a portion of the source contact sacrificial material, and a portion of the top semiconductive material to form stepped openings comprises etching a slot in the top semiconductive material, forming a liner adjacent to the slot, etching an additional slot through the liner and through the source contact sacrificial material and the bottom semiconductive material, and removing the remaining portion of the liner.
